(19) United States
(12) Patent Application Publication
(10) Pub. No.: US 2023/0141508 A1
(43) Pub. Date: May 11, 2023

(54) METHODS AND APPARATUS FOR AUTO TUNING COOLING OF COMPUTE DEVICES BASED ON WORKLOADS

(71) Applicant: Intel Corporation, Santa Clara, CA (US)

(72) Inventors: Christopher MacNamara, Ballyclough (IE); Kshitij Arun Doshi, Tempe, AZ (US); Francesc Guim Bernat, Barcelona (ES); John J. Browne, Limerick (IE); Amruta Misra, Bangalore (IN)

(21) Appl. No.: 18/148,317

(22) Filed: Dec. 29, 2022

(51) Int. Cl. H05K 7/20; H05K 7/14

(52) U.S. Cl. CPC H05K 7/20836; H05K 7/1494

(57) ABSTRACT

Methods, apparatus, systems, and articles of manufacture are disclosed to auto tune data center cooling based on workloads. Disclosed herein is an apparatus including processor circuitry to determine environmental conditions setpoint(s) based on at least one of a future workload status or a current workload status of devices within a data center.

### FIELD OF THE DISCLOSURE

This disclosure relates generally to compute devices and, more particularly, to methods and apparatus for auto tuning cooling compute devices based on workloads.

### BACKGROUND

Data centers are used to house many high-performance computing devices (e.g., servers, desktop computers, routers, modems, etc.). These high-performance computing devices heat up as they execute workloads. Data centers usually have an air conditioning/environmental control system to change environmental conditions (e.g., temperature, humidity, etc.) where the computing devices are housed so the computing devices can maintain operability and reduce the risk of damage or performance loss.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 is a system level diagram of an example environmental control system of FIG. 2.

FIG. 18 is a block diagram of an example implementation of the environmental controller circuitry of FIG. 17.

FIG. 19 is a flowchart representative of example machine readable instructions and/or example operations that may be performed by example processor circuitry to implement the environmental controller circuitry of FIG. 18.

FIG. 20 is a flowchart representative of example machine readable instructions and/or example operations that may be performed by example processor circuitry to implement the environmental setpoint determination circuitry of FIG. 18.

FIG. 21 is a block diagram of an example processing platform including processor circuitry structured to execute the example machine readable instructions and/or the example operations of FIGS. 19 and/or 20 to implement the example environmental controller circuitry of FIG. 18.

FIG. 22 is a block diagram of an example implementation of the processor circuitry of FIG. 21.

FIG. 23 is a block diagram of another example implementation of the processor circuitry of FIG. 21.

FIG. 24 is a block diagram of an example software distribution platform (e.g., one or more servers) to distribute software (e.g., software corresponding to the example machine readable instructions of FIGS. 19 and/or 20) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Data centers are used to house servers and other various high-performance computing components/devices. One drawback of these computing devices is that they generate a large amount of heat due to workloads they execute. When the computing devices execute these workloads, the computing devices require cooling to maintain a temperature within the computing devices to allow the hardware performing the workloads to function properly. When temperatures get too high, the hardware within the computing devices can throttle (e.g., performance is reduced) and sometimes even become damaged.

In some data centers, cooling is achieved by forced air passing over heat producing components (e.g., servers or other electronic components/devices) to draw away thermal energy from the components. The effectiveness of such cooling often depends upon the ambient temperature and/or other conditions (e.g., humidity) of the environment/climate surrounding the heat producing components. Typically, the ambient temperature and/or other conditions of the environment within a data center are set and/or controlled manually (e.g., a facility engineer must manually change the temperature). Although the servers/computing devices encompass a monitoring system to monitor the temperature of the servers/computing devices during operation, the temperature monitoring of the servers/computing devices and the ability to modify the ambient conditions to assist in cooling the servers/computing devices when they overheat are disconnected, requiring user intervention to maintain stability within the data center.

In some examples, the data center is made up of multiple plots, where each plot includes a specific number of servers/computing systems. In such an example, where a plot includes, e.g., ten computing devices that are performing a heavy workload (e.g., generating a large amount of heat), that plot may need to be set to a significantly cooler temperature than another plot including, e.g., five computing devices performing a light workload and generating a small amount of heat. In some data centers, manually providing temperature changes to the ambient air surrounding nodes is tedious and inefficient. Such manual control is also reactionary in that it occurs after temperature has changed. It can be more difficult to cool devices after they have heated up than to proactively prepare for an upcoming change due to, for example, increasing workloads. Therefore, it is beneficial to create a system (e.g., for data centers, edge applications, and/or cloud services) in which the monitored temperatures and executed/upcoming workloads of the server/computing device/plot(s) are used to control the ambient conditions surrounding the server/computing device/plot(s) to eliminate inefficiencies associated with manually modifying climate/environmental conditions.

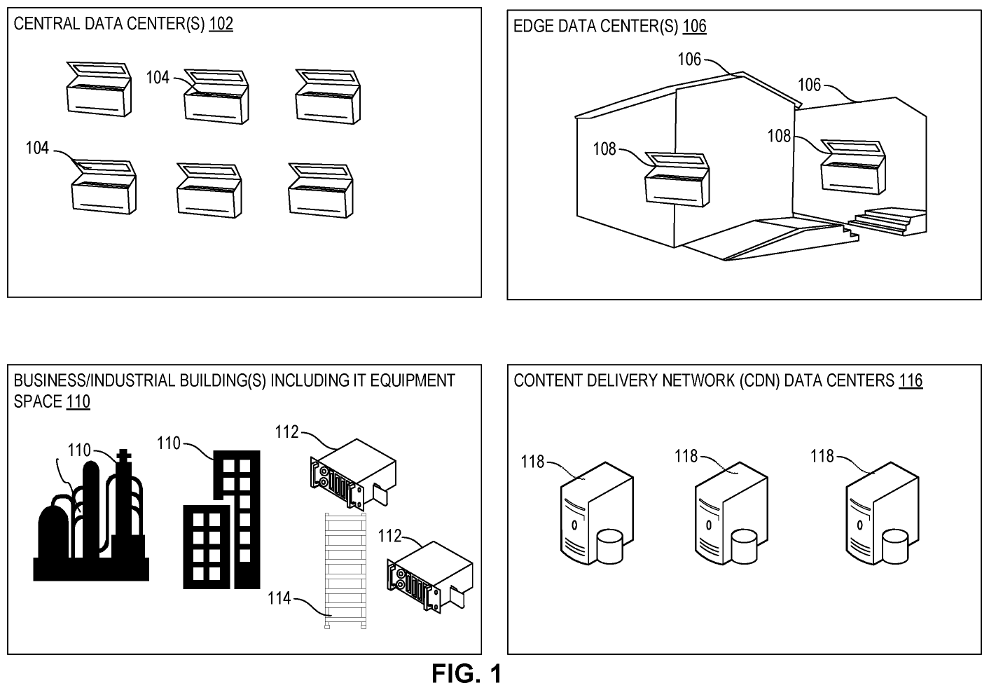

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

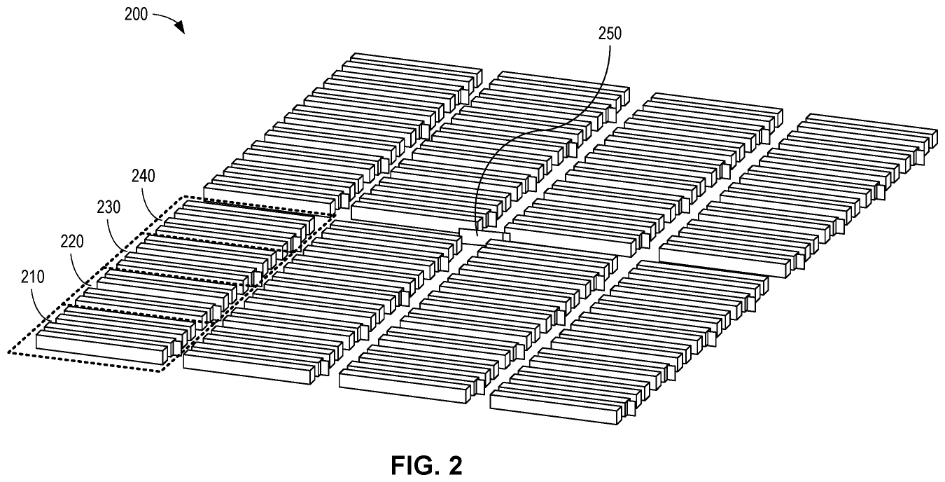

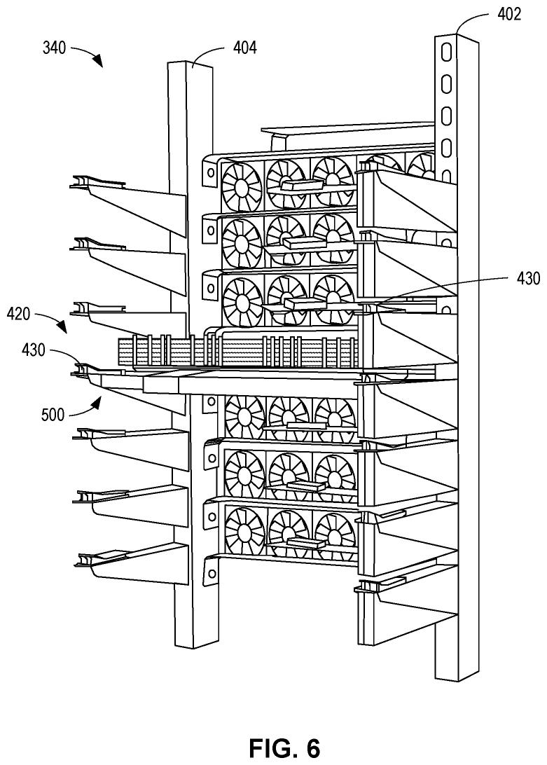

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniB and or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

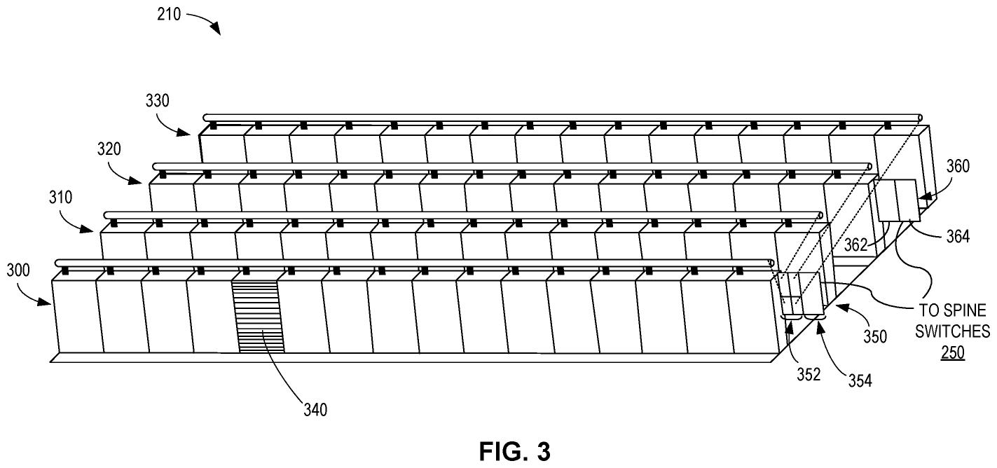

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

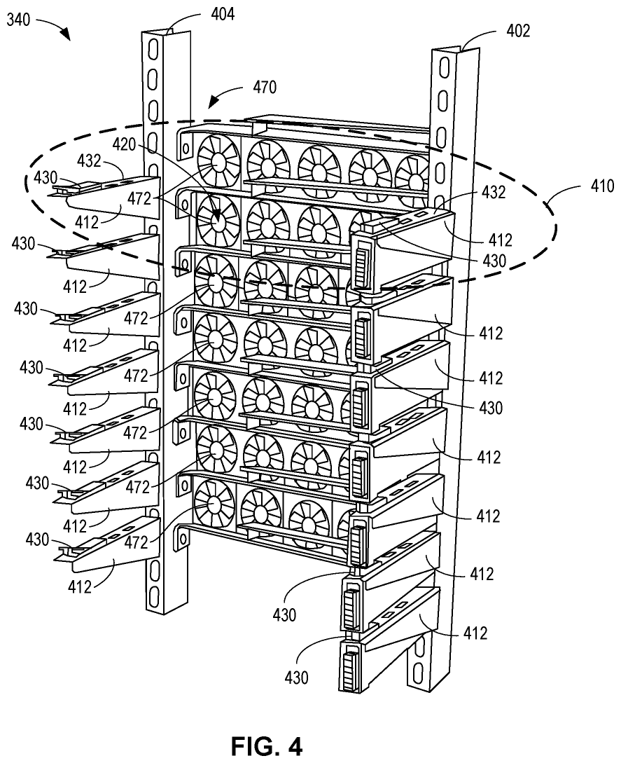

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

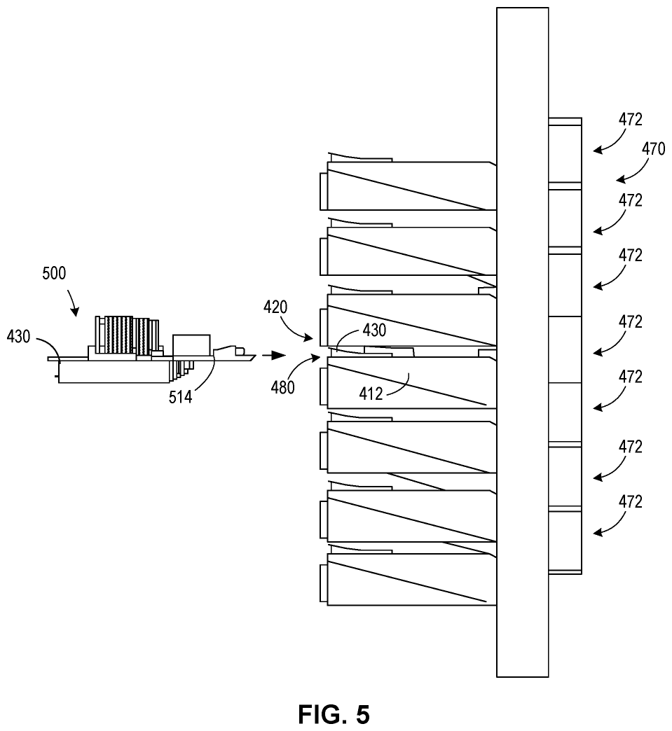

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

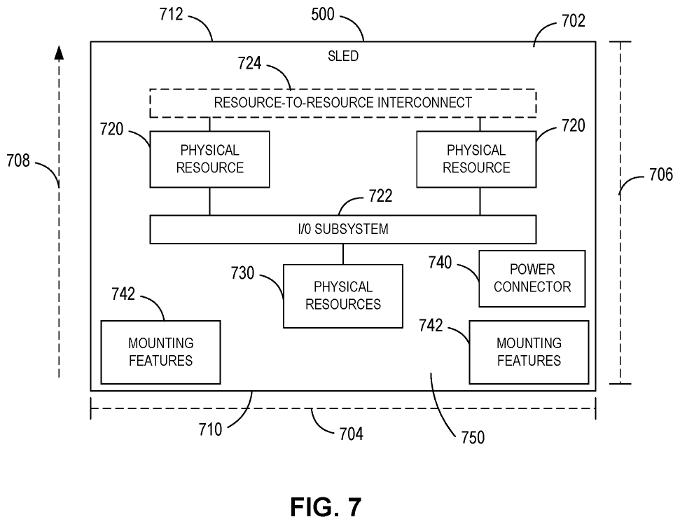

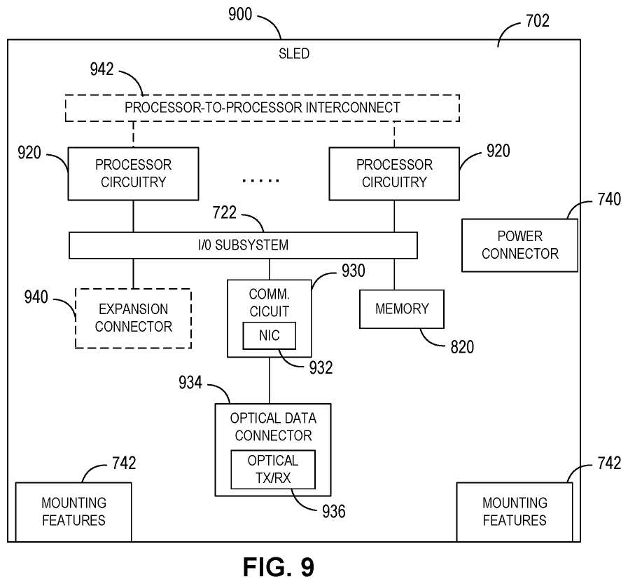

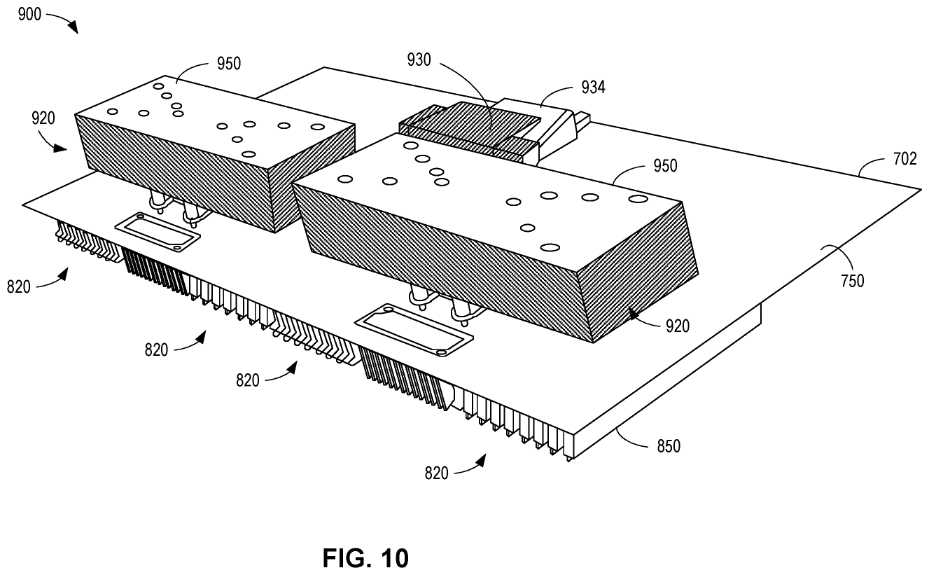

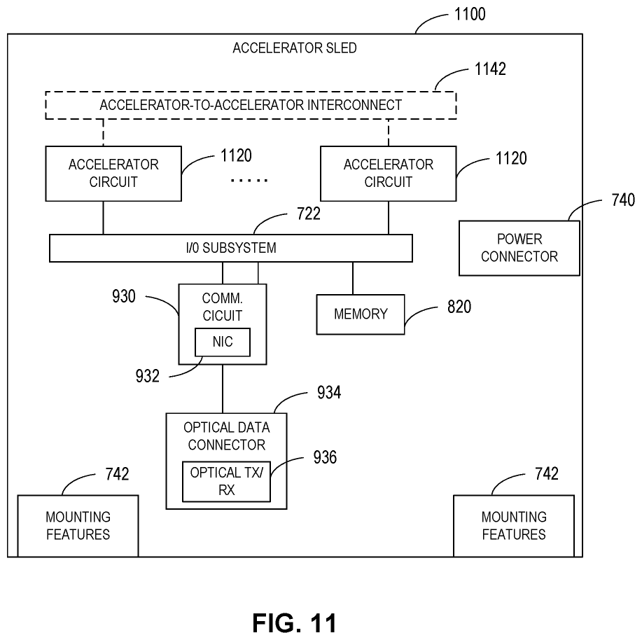

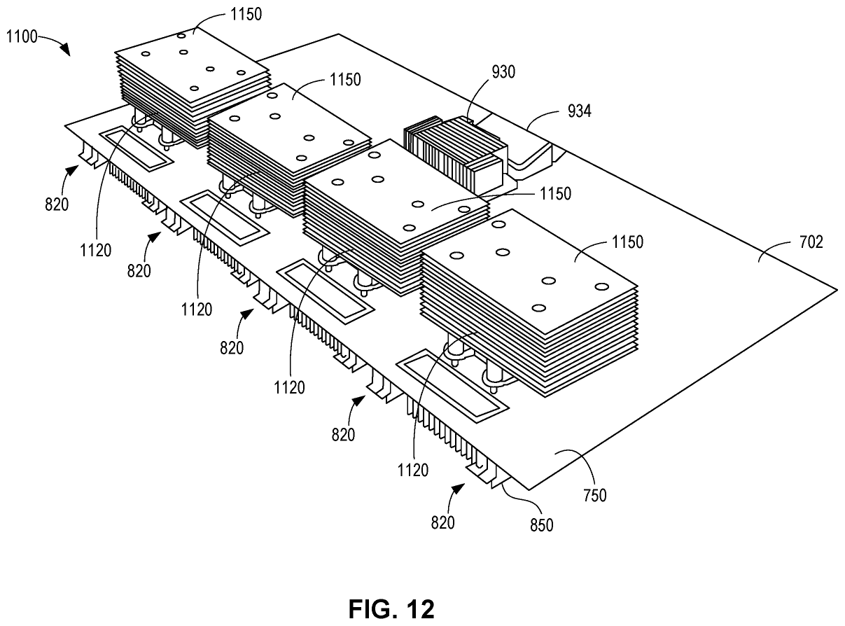

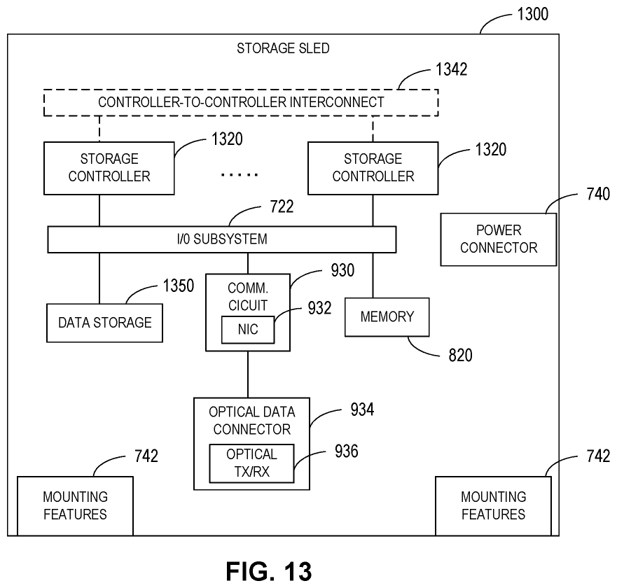

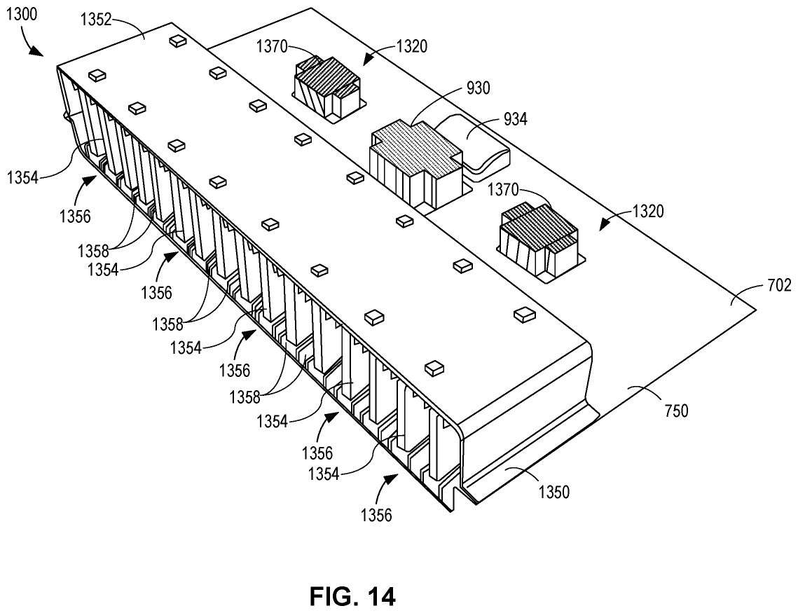

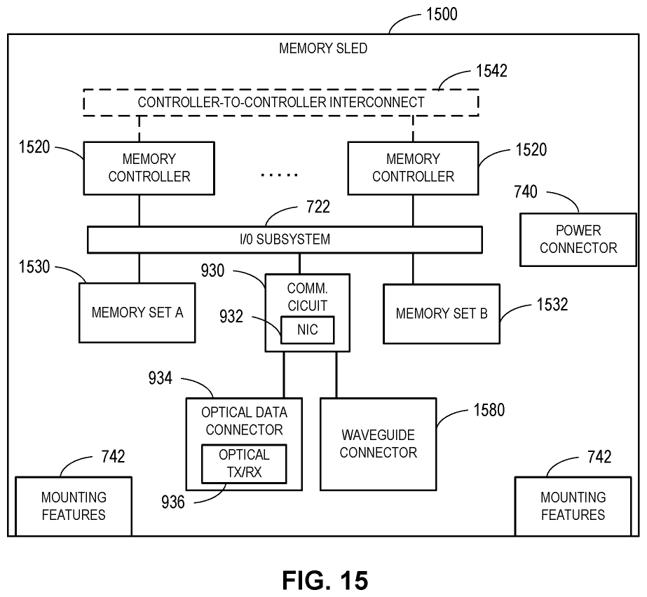

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDRS data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

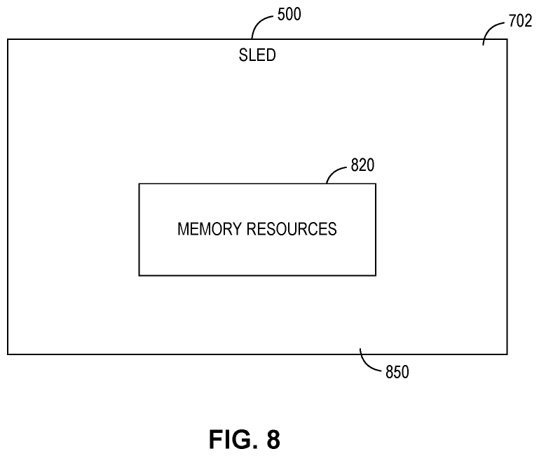

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPointTM memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

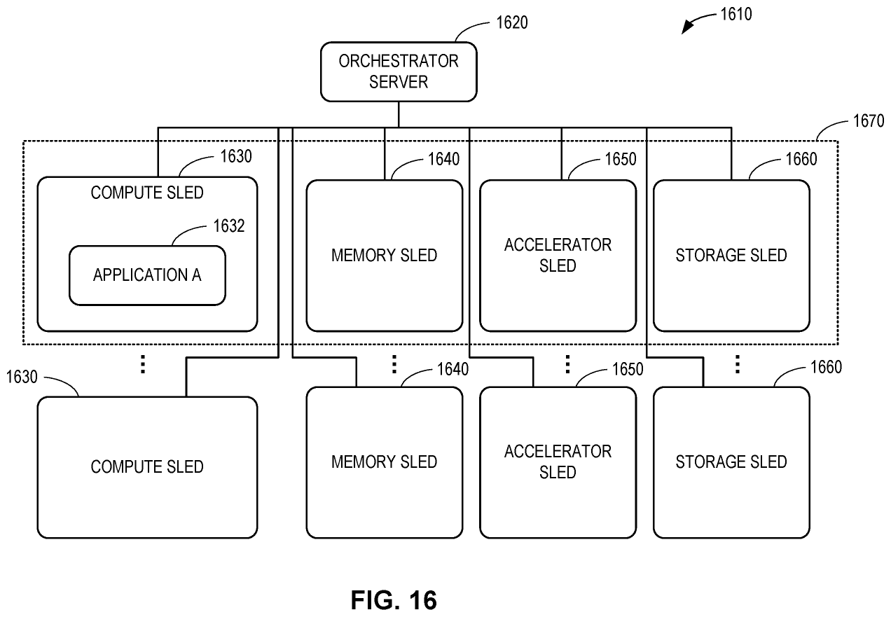

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

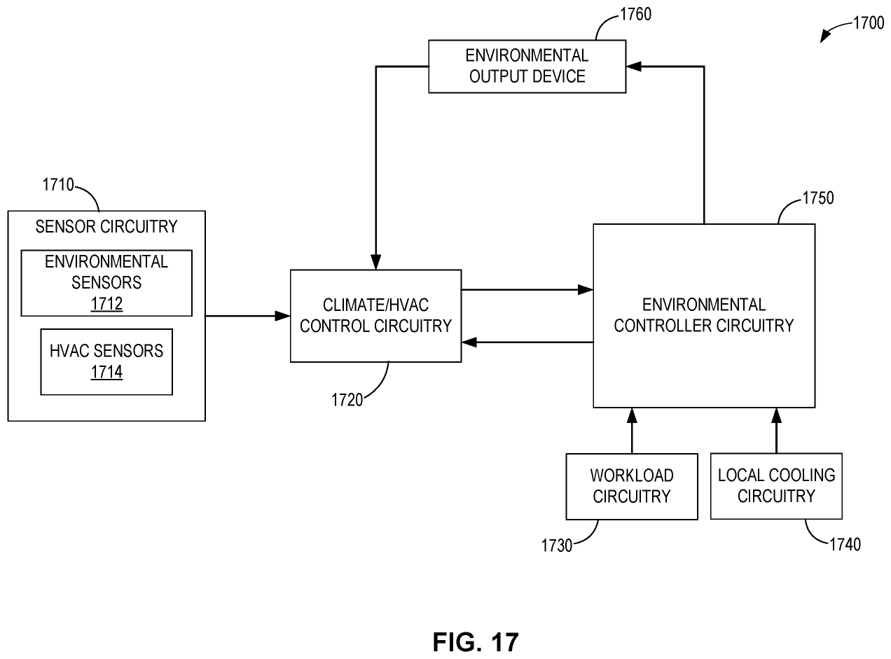

FIG. 17 is a system diagram of an example environmental control system 1700 that can be used to moderate climate/environmental conditions in the data center 200. The example environmental control system 1700 includes a sensor circuitry 1710, climate/HVAC control circuitry 1720, workload circuitry 1730, local cooling circuitry 1740, environmental controller circuitry 1750, and an environmental output device 1760.

The sensor circuitry 1710 senses environmental/climate conditions in the data center 200. The sensor circuitry 1710 includes environmental sensors 1712 and heating, ventilation, and air conditioning (HVAC) sensors 1714. In some examples, the environmental sensors 1712 sense climate/environmental conditions in the ambient air in the data center 200 such as temperature and humidity. In some examples, the HVAC sensors 1714 detect the operability and environmental/climate conditions of the HVAC system such as whether the HVAC system is operable or in failure, the climate/environmental conditions inside the HVAC ducts (e.g., temperature, humidity, etc.), the amount the HVAC system can change the climate/environmental conditions in the data center 200 (e.g., determining whether the HVAC system can meet the cooling needs), etc.

The climate/HVAC control circuitry 1720 is able to change the climate/environmental conditions in the data center 200. In some examples, the climate/HVAC control circuitry 1720 receives sensor data from the sensor circuitry 1710 representative of the ambient conditions. In such an example the climate/HVAC control circuitry 1720 utilizes the sensor data to identify differences from a desired environmental condition and to assist in determining a climate/environment conditions setpoint (e.g., a new temperature setpoint, a new humidity setpoint, and/or any value related to the ambient climate/environment) which will bring environmental conditions into a desired range.

In some examples, the data center 200 includes plots of servers/computing devices. As used herein, a plot refers to a number of servers/computing devices less than the total number of servers/computing devices in the data center 200. In some examples, the plots include a cluster of servers/computing devices performing the same or similar workloads. In such an example, the servers/computing devices performing the same/similar workloads can have climate/environmental conditions tuned independently of other plots to accommodate differences in workloads and cooling needs. In other examples, the plots include servers/computing devices performing vastly different workloads (e.g., some performing heavy workloads, some performing light workloads, or any combination thereof). In such an example, the plots may be organized and workloads may be distributed such that plots of servers/computing devices collectively perform workloads that produce heat below a certain threshold to keep cooling needs in the data center 200 consistent throughout multiple plots or throughout the entire data center 200.

The workload circuitry 1730 obtains information related to a workload status of one or more servers (e.g., the orchestrated server 1620) and/or computing devices in the data center 200 (e.g., plots). In some examples, workloads increase heat generation in the servers/computing devices/plots due to an increase in utilization of computing resources needed to accomplish the workload. In some examples, the workload status includes information related to computing performance of the plots such as server power limit, CPU core frequencies, turbo limits, CPU core temperatures, fan speed/status, workload key performance indicators (KPIs) such as throughput and latency, etc. Any additional or combination of computing performance indicators may be interchangeably used herein to represent the workload status of a server/computing device/plot. In some examples, similar performance parameters (such as CPU temperature, clock speed and/or frequency) may be grouped together and/or weighted to impact the environmental conditions setpoint. The workload status may reflect current workloads running on the server(s) and/or computing devices and/or future workloads expected to run on those server(s) and/or computing devices.

The local cooling circuitry 1740 obtains information related to a local cooling status (e.g., local cooling KPIs) of the server/computing device/plot. In some examples, the local cooling status includes current system temperature, location within the data center 200, temperature limits (e.g., min and max operating temperatures), cooling headroom availability (e.g., an amount of cooling still available locally based on the current climate/environmental conditions), etc. As used herein, local cooling refers to the cooling available on the server/computing device/plot individually independent of the climate/environmental conditions.

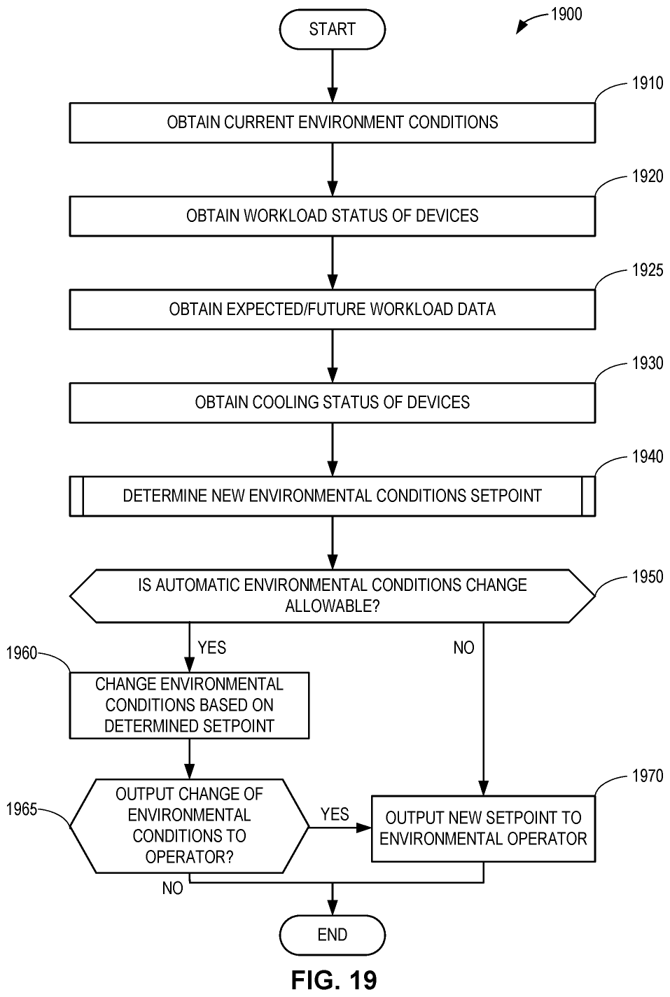

The environmental controller circuitry 1750 determines the environmental conditions setpoint based on information from the climate/HVAC control circuitry 1720, the workload circuitry 1730, and the local cooling circuitry 1740. The climate/environmental conditions may also include local climate conditions at individual server racks and/or server bays. Such local climate conditions may indicate smaller subsets of servers (e.g., 1 or more) and/or may indicate differing climate/environmental conditions between those smaller subsets of servers. In some examples, the environmental controller circuitry 1750 recommends the environmental conditions setpoint and outputs the recommendation to the environmental output device 1760. A human operator then determines whether to follow the recommendation by manually entering commands for the climate/HVAC control circuitry 1720 and/or by manually changing the thermostat, humidifier, etc. In some examples, the environmental controller circuitry 1750 additionally or alternatively provides the climate control setpoint directly to the climate/HVAC control circuitry 1720 to cause automatic changes in the ambient conditions without user intervention. In some examples, the environmental conditions setpoint is propagated back to a software manager (e.g., operating system (OS), orchestrator, etc.) to keep the software manager aware of the new environmental conditions setpoint. Such an example may be necessary to maintain logs of climate/environmental conditions changes, policy concerns, etc. In some examples, the environmental controller circuitry 1750 is instantiated by processor circuitry executing environmental controller instructions and/or configured to perform operations such as those represented by the flowcharts of FIGS. 19 and/or 20.

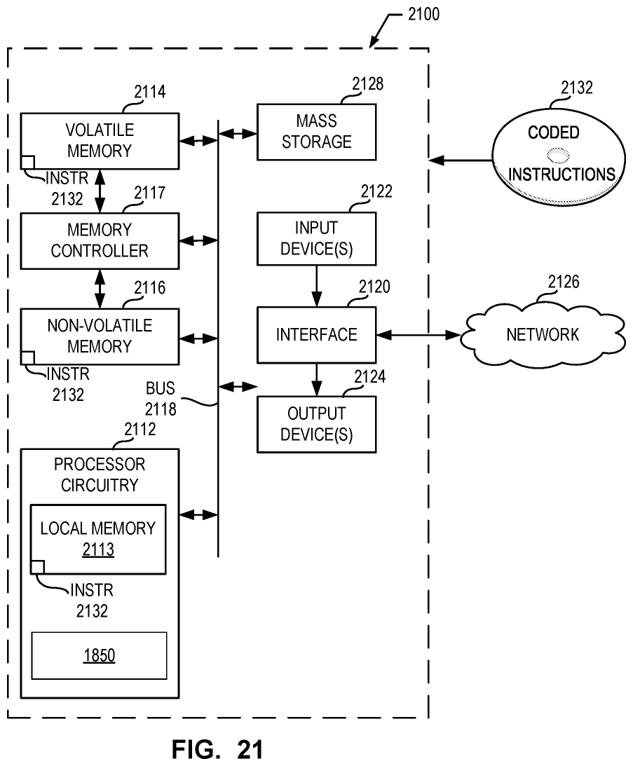

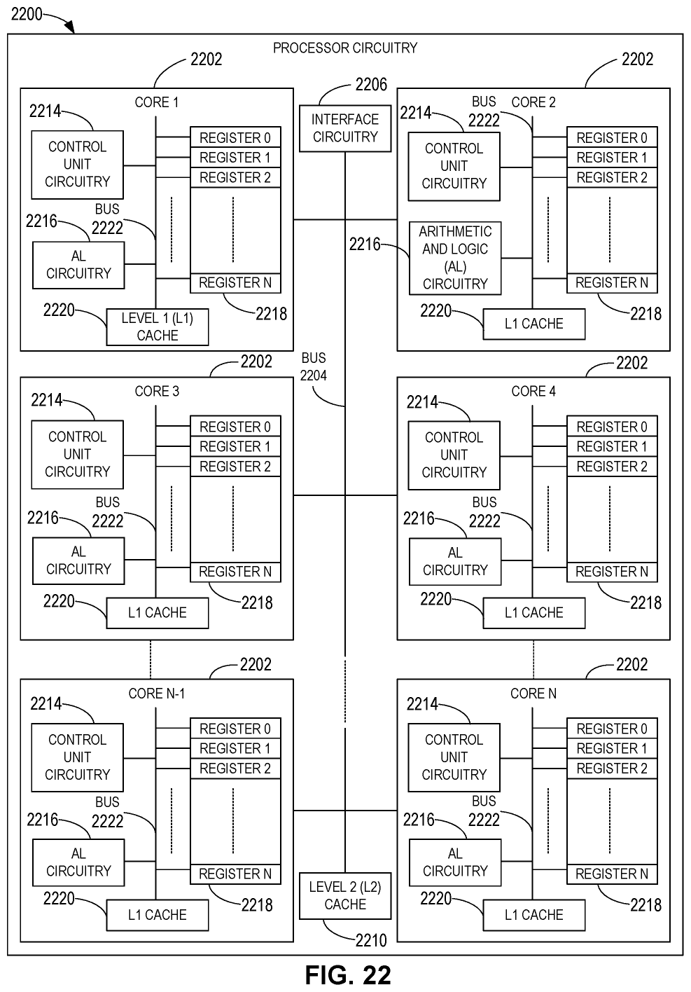

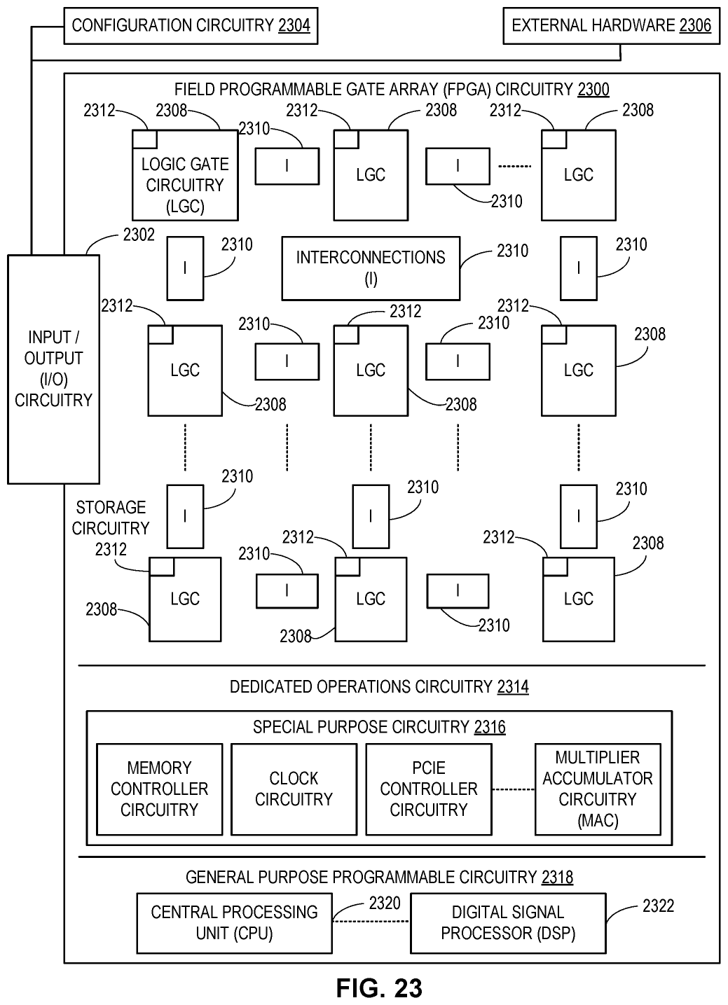

In some examples, the environmental controller circuitry 1750 implements means for obtaining information related to current and/or future operation(s) and/or workloads of devices within the data center 200, such as workload status from the workload circuitry 1730 and local cooling status from the local cooling circuitry 1740. In some examples, the environmental controller circuitry 1750 may be instantiated by processor circuitry such as the example processor circuitry 2112 of FIG. 21. For instance, the environmental controller circuitry 1750 may be instantiated by the example microprocessor 2200 of FIG. 22 executing machine executable instructions such as those implemented by at least blocks 1920 and 1930 of FIG. 19. In some examples, the environmental controller circuitry 1750 may be instantiated by hardware logic circuitry, which may be implemented by an ASIC, XPU, or the FPGA circuitry 2300 of FIG. 23 structured to perform operations corresponding to the machine readable instructions. Additionally or alternatively, the environmental controller circuitry 1750 may be instantiated by any other combination of hardware, software, and/or firmware. For example, the environmental controller circuitry 1750 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the environmental controller circuitry 1750 includes means for controlling a climate/environmental condition (e.g., to achieve a climate/environmental condition different than the current climate/environmental condition) for any one of or more plots within the data center 200 based on the environmental conditions setpoint. The environmental controller circuitry 1750 may be instantiated by the example microprocessor 2200 of FIG. 22 executing machine executable instructions such as those implemented by at least blocks 1960 and 1970 of FIG. 19. As disclosed above, in some examples, the environmental controller circuitry 1750 may be instantiated by hardware logic circuitry, which may be implemented by an ASIC, XPU, or the FPGA circuitry 2300 of FIG. 23 structured to perform operations corresponding to the machine readable instructions.

As disclosed above, in some examples, a human may decide whether to change the climate/environmental conditions manually by changing a thermostat, a humidifier, etc. In some examples, the operator may determine that the environmental conditions setpoint is not appropriate for the current state of the data center 200 (or individual plot) and may choose not to manually change the climate/environmental conditions. In other examples, the environmental output device 1760 manually changes the climate/environmental conditions based on the recommendation of the environmental conditions setpoint.

As disclosed above, in some examples, the climate/HVAC control circuitry 1720 changes the climate/environmental conditions automatically without an operator manually changing the thermostat, humidifier, etc. In some examples, the climate/HVAC control circuitry 1720 directly sets the environmental/climate conditions (e.g., changes the HVAC settings such as thermostat setpoint, humidity level, etc.) based on the environmental conditions setpoint.

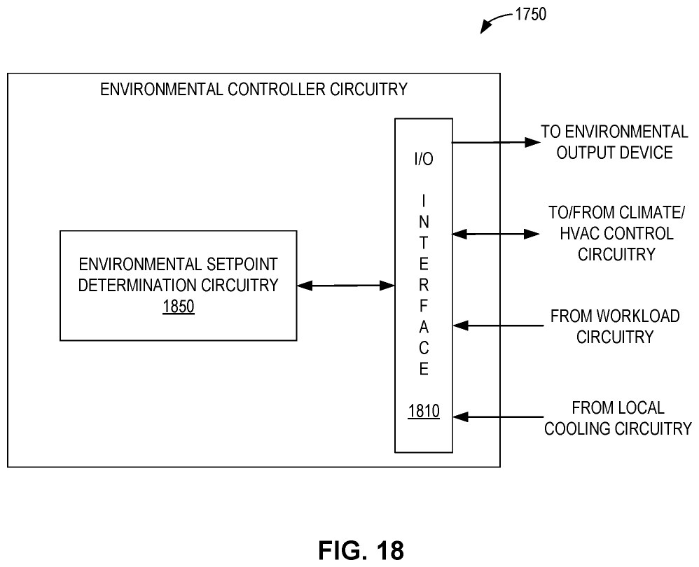

FIG. 18 is a block diagram of an example implementation of the environmental controller circuitry 1750 of FIG. 17. The environmental controller circuitry 1750 determines the climate/environmental condition setpoint. The environmental controller circuitry 1750 of FIG. 18 may be instantiated (e.g., creating an instance of, bring into being for any length of time, materialize, implement, etc.) by processor circuitry such as a central processing unit executing instructions. Additionally or alternatively, the environmental controller circuitry 1750 of FIG. 18 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 18 may, thus, be instantiated at the same or different times. Some or all of the circuitry may be instantiated, for example, in one or more threads executing concurrently on hardware and/or in series on hardware. Moreover, in some examples, some or all of the circuitry of FIG. 18 may be implemented by microprocessor circuitry executing instructions to implement one or more virtual machines and/or containers.

The example environmental controller circuitry 1750 of FIG. 18 includes an I/O Interface 1810 and environmental setpoint determination circuitry 1850.

The environmental setpoint determination circuitry 1850 communicates with the climate/HVAC control circuitry 1720 via the I/O Interface 1810 to obtain current climate/environmental condition data. The current climate/environmental condition data may include sensor data from the sensor circuitry 1710. The setpoint determination circuitry 1850 communicates with the workload circuitry 1730 via the I/O Interface 1810 to obtain the current and/or future workload status of any one of or combination of servers/computing devices/plots. In some examples, the setpoint determination circuitry 1850 is instantiated by processor circuitry such as that shown below.

The setpoint determination circuitry 1850 communicates with the local cooling circuitry 1740 via the I/O Interface 1810 to obtain the local cooling status of any one of or combination of servers/computing devices/plots.

The environmental setpoint determination circuitry 1850 determines the environmental conditions setpoint based on information obtained/retrieved via the I/O interface 1810. In some examples, the environmental conditions setpoint includes a temperature and/or a humidity setpoint. In some examples, the environmental setpoint determination circuitry 1850 includes a bi-directional guard band for limiting the environmental conditions setpoint (e.g., limiting/changing/updating of the setpoint to within upper and lower boundaries) to protect and/or maintain performance of the servers/computing devices/plots. In such an example, the environmental setpoint determination circuitry 1850 may execute a parameterization function based on the collected information obtained via the I/O interface 1810 to determine appropriate limitations on the environmental conditions setpoint. In some examples, the data from the workload circuitry 1730 includes an identification of upcoming workloads. In some such examples, the environmental setpoint determination circuitry 1850 does not merely consider current climate/environmental conditions, but instead considers heat to be generated in the future based on upcoming workload(s) and/or increases in workload(s). Moreover, the climate setpoint circuitry 1850 may additionally or alternatively consider an upcoming reduction in heat generation to be caused by expected/future workload(s) and/or decreases in upcoming workload(s). As a result, the environmental setpoint determination circuitry 1859 may get ahead of climate changes by adjusting the setpoint prospectively for upcoming heat increases or heat decreases corresponding to upcoming workload(s). As a result, the HVAC system can be adjusted to avoid falling behind in sustaining a desired temperature in view of upcoming heat generation by increasing cooling when heat generation is expected to increase and/or to avoid spending excess energy on cooling when heat generation is expected to decrease. This forward looking approach saves energy while maintaining the climate/environmental conditions within acceptable ranges for the server(s) and/or other computing devices. In some examples, the environmental setpoint determination circuitry 1850 is instantiated by processor circuitry executing climate setpoint determination instructions and/or configured to perform operations such as those represented by the flowcharts of FIGS. 19 and/or 20.

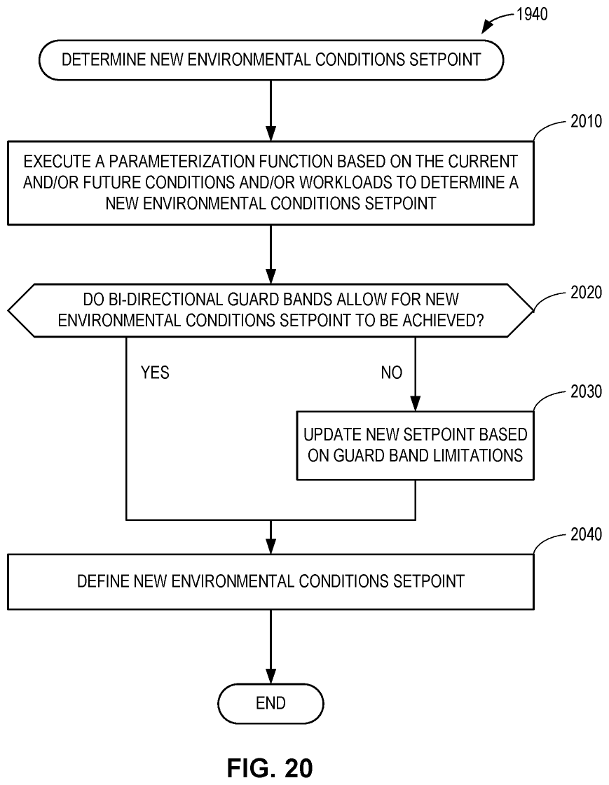

In some examples, the environmental controller circuitry 1750 implements means for determining a climate/environmental conditions setpoint. In some examples, the environmental setpoint determination circuitry 1850 may be instantiated by processor circuitry such as the example processor circuitry 2112 of FIG. 21. For instance, the environmental setpoint determination circuitry 1850 may be instantiated by the example microprocessor 2200 of FIG. 22 executing machine executable instructions such as those implemented by at least blocks 1940 of FIGS. 19 and 2010, 2020, 2030, and 2040 of FIG. 20. In some examples, the environmental setpoint determination circuitry 1850 may be instantiated by hardware logic circuitry, which may be implemented by an ASIC, XPU, or the FPGA circuitry 2300 of FIG. 23 structured to perform operations corresponding to the machine readable instructions of at least blocks 1940 of FIGS. 19 and 2010, 2020, 2030, and 2040 of FIG. 20. Additionally or alternatively, the environmental setpoint determination circuitry 1850 may be instantiated by any other combination of hardware, software, and/or firmware. For example, the environmental setpoint determination circuitry 1850 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The environmental setpoint determination circuitry 1850 outputs the environmental conditions setpoint to control the climate/environmental conditions in the data center 200. In some examples, the environmental setpoint determination circuitry 1850 outputs the environmental conditions setpoint to the climate/HVAC control circuitry 1720 directly to automatically cause a change to the climate/environmental conditions, without user/operator intervention. In some examples, the environmental setpoint determination circuitry 1850 outputs the environmental conditions setpoint to the environmental output device 1760 and/or the data center operator. In some examples, the environmental conditions setpoint is propagated back to the software manager (e.g., operating system (OS), orchestrator, etc.) to keep the software manager aware of the new environmental conditions setpoint. In some examples, the setpoint determination circuitry 1850 is instantiated by processor circuitry executing climate setpoint output instructions and/or configured to perform operations such as those represented by the flowchart of FIG. 19.

While an example manner of implementing the environmental controller circuitry 1750 of FIG. 17 is illustrated in FIG. 18, one or more of the elements, processes, and/or devices illustrated in FIG. 18 may be combined, divided, re-arranged, omitted, eliminated, and/or implemented in any other way. Further, the example environmental setpoint determination circuitry 1850 and/or, more generally, the example environmental controller circuitry 1750 of FIG. 17, may be implemented by hardware alone or by hardware in combination with software and/or firmware. Thus, for example, any of the example environmental setpoint determination circuitry 1850 and/or, more generally, the example environmental controller circuitry 1750, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example environmental controller circuitry 1750 of FIG. 17 may include one or more elements, processes, and/or devices in addition to, or instead of, those illustrated in FIG. 18, and/or may include more than one of any or all of the illustrated elements, processes and devices.

A flowchart representative of example machine readable instructions, which may be executed to configure processor circuitry to implement the environmental controller circuitry 1750 of FIG. 18, is shown in FIGS. 19 and/or 20. The machine readable instructions may be one or more executable programs or portion(s) of an executable program for execution by processor circuitry, such as the processor circuitry 2112 shown in the example processor platform 2100 discussed below in connection with FIG. 21 and/or the example processor circuitry discussed below in connection with FIGS. 22 and/or 23. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowchart illustrated in FIGS. 19 and/or 20, many other methods of implementing the example environmental controller circuitry 1750 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 19 and/or 20 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 19 is a flowchart representative of example machine readable instructions and/or example operations that may be executed and/or instantiated by processor circuitry to output a climate/environmental conditions setpoint. The climate/environmental conditions modification process 1900 of FIG. 19 begin at block 1910, at which the environmental setpoint determination circuitry 1850 obtains the current climate/environmental conditions of the data center 200. In some examples, the current climate/environmental conditions include a current temperature, a current humidity, and/or and other climate/environmental condition that may be useful for maintaining operability of servers/computing devices/plots.

The environmental setpoint determination circuitry 1850 obtains the workload status of the servers/computing devices/plots from the workload circuitry 1730. (Block 1920). In some examples, the workload status includes computing performance parameters such as server power limit, CPU core frequencies, turbo limits, CPU core temperatures, fan speed/status, workload key performance indicators (KPIs) such as throughput and latency, etc. Any one of or combination of computing performance parameters may be interchangeably used herein to populate the workload status.

The environmental setpoint determination circuitry 1850 obtains expected/future workload data from the workload circuitry 1730. (Block 1925). In some examples, the data from the workload circuitry 1730 includes an identification of upcoming workloads. In some such examples, the environmental setpoint determination circuitry 1850 does not merely consider current climate/environmental conditions, but instead considers changes in heat to be generated in the future based on the upcoming workloads. Such examples may include heat increases due to external environmental factors (e.g., rising sun, setting sun, weather, etc.), time of day, workloads performed on regular intervals (e.g., workloads performed on an hourly/daily/weekly/etc. basis), heat increases due to inefficiencies of hardware components as they age, etc. In some examples, a machine learning/artificial intelligence model may be implemented to predict and/or identify changes to be made in the HVAC settings to maintain the desired conditions (e.g., across a data warehouse, at a plot, at a rack, at a server, etc.) and/or adjust the environmental conditions setpoint based on upcoming workloads and/or changes to climate/environmental conditions. As disclosed above, considering expected/future workloads increases efficiency of the HVAC system and saves energy by enabling proactive adjustment to HVAC settings before workload conditions actually occur.

The environmental setpoint determination circuitry 1850 obtains the local cooling status of the servers/computing devices/plots from the local cooling circuitry 1740. (Block 1930). In some examples, the local cooling status includes information related to the cooling of local servers/computing devices/plots such as current system temperature, location within the data center 200, temperature limits, cooling headroom availability (e.g., the amount of cooling still available locally based on the current conditions), etc. In the examples disclosed herein, the operations of blocks 1910, 1920, 1925, and 1930 can be performed in parallel or in series. Additionally, the order in which the operations of blocks 1910, 1920, 1925, and 1930 are performed can be interchanged into any order as disclosed above.

Once the current climate/environmental conditions, the workload status (current and/or expected/future), and the local cooling status are obtained, the environmental setpoint determination circuitry 1850 determines the environmental conditions setpoint based on the information obtained. (Block 1940). In some examples, as disclosed in reference to FIG. 20, the environmental setpoint determination circuitry 1850 executes a parameterization function that analyzes the information obtained to output the appropriate environmental conditions setpoint to maintain operability of the servers/computing devices/plots. In some examples, as disclosed also in reference to FIG. 20, the environmental setpoint determination circuitry 1850 implements a bi-directional guard band to limit the environmental conditions setpoint based on a variety of factors such as current workload commitment, risk factors to hardware and/or software policy, etc.

As disclosed above, in some examples, the environmental setpoint determination circuitry 1850 does not merely consider current climate/environmental conditions, but instead considers changes in heat generation expected to occur in the future based on the upcoming workloads. As a result, the environmental setpoint determination circuitry 1859 may get ahead of climate changes by adjusting the setpoint prospectively for upcoming heat increases or heat decreases. As a result, the HVAC system (e.g., the climate/HVAC control circuitry 1720) can be adjusted to avoid falling behind on heat generation by increasing cooling when heat generation is expected to increase and/or to avoid spending excess energy on cooling when heat generation is expected to decrease. This forward looking approach saves energy while maintaining the climate/environmental conditions within acceptable ranges for the server(s) and/or other computing devices.

In some examples, the environmental setpoint determination circuitry 1850 may determine that it is more energy efficient to cool the data center before workloads begin and to maintain a temperature/humidity/etc. than to reactively cool after temperatures approach/near or even exceed allowable thresholds. Such an example reduces greenhouse gas emissions since it is more energy efficient to maintain a temperature than it is to reactively reach a temperature. Moreover, savings also occur if active cooling is stopped or avoided when it is determined to be not needed to avoid exceeding a temperature limit due to expected decrease in workloads.

When the environmental setpoint determination circuitry 1850 determines the environmental conditions setpoint, the environmental setpoint determination circuitry 1850 determines whether the example environmental control system 1700 permits changing the climate/environmental conditions automatically. (Block 1950). In some examples, the environmental control system 1700 prohibits the automatic change of the climate/environmental conditions due to sensitivity (e.g., highly valuable workloads, fragile hardware components, etc.) of the servers/computing devices/plots in the data center 200. In other examples, the environmental control system 1700 permits the setpoint determination circuitry 1850 to automatically change the climate/environmental conditions to protect the devices from climate-related damage and/or to maintain performance of the devices performing a workload. In some examples, the environmental setpoint determination circuitry 1850 may proactively set the climate/environmental conditions based on expected/future workloads.

When the environmental setpoint determination circuitry 1850 determines that the environmental control system 1700 permits changing the climate/environmental conditions automatically (e.g., block 1950 returns a result of YES), the environmental setpoint determination circuitry 1850 changes the climate/environmental conditions in the data center 200 to the environmental conditions setpoint. (Block 1960).

The environmental setpoint determination circuitry 1850 then determines whether the environmental conditions setpoint is to be outputted to the environmental output device 1760 and/or the data center operator. (Block 1965). In some examples, the environmental output device 1760 and/or the data center operator may desire knowing the environmental conditions setpoint even when the environmental controller circuitry 1750 changes the climate/environmental conditions automatically. In some examples, the environmental conditions setpoint is propagated back to the software manager (e.g., operating system (OS), orchestrator, etc.) to keep the software manager aware of the new environmental conditions setpoint. Such information may be used as a separate record/log of the data center 200 climate/environmental conditions changing events, a notice for the environmental output device 1760 and/or the data center operator to double check the status of the data center 200, etc.

When the environmental setpoint determination circuitry 1850 determines that the environmental control system 1700 does not permit automatic changes to the climate/environmental conditions (e.g., block 1950 returns a result of NO) or when the environmental setpoint determination circuitry 1850 determines that the environmental conditions setpoint is to be outputted to the environmental output device 1760 and/or the data center operator after an automatic change to the climate/environmental conditions (e.g., block 1965 returns a result of YES), then the environmental setpoint determination circuitry 1850 outputs the environmental conditions setpoint to the environmental output device 1760 and/or the data center operator. (Block 1970). In some examples, the environmental output device 1760 and/or the data center operator may decide to change the corresponding climate/environmental conditions in the data center 200 based on the output of the environmental conditions setpoint. In other examples, such as when the environmental controller circuitry 1750 automatically changes the corresponding climate/environmental conditions, the environmental output device 1760 and/or the data center operator may decide to monitor the corresponding climate change to ensure the environmental conditions setpoint is met.

When the environmental setpoint determination circuitry 1850 determines that the environmental conditions setpoint is not outputted to the environmental output device 1760 and/or the data center operator after an automatic change to the corresponding climate/environmental conditions (e.g., block 1965 returns a result of NO) or when the environmental conditions setpoint is output to the environmental output device 1760 and/or the data center operator, then the climate/environmental conditions modification process 1900 ends. The climate/environmental conditions modification process 1900 may execute as frequently as needed to maintain operability of the servers/computing devices/plots in the data center 200 (e.g., continuously, after a certain passage of time, after a certain temperature is reached in the data center 200, after a certain temperature is reached inside a server/computing device/plot, etc.).

FIG. 20 is a flowchart representative of example machine readable instructions and/or example operations that may be executed and/or instantiated by processor circuitry to determine a climate/environmental conditions setpoint. The climate/environmental conditions determination process 1940 of FIG. 20 begin at block 2010, at which the environmental setpoint determination circuitry 1850 executes a parameterization function based on the current and/or future climate/environmental conditions and/or workloads to determine the environmental conditions setpoint.

In some examples, the parameterization function includes a weighted analysis of the information obtained to determine the appropriate environmental conditions setpoint. For example, the environmental setpoint determination circuitry 1850 could determine that the operating temperature of the servers/computing devices/plots is the most important parameter to determine the appropriate environmental conditions setpoint. In such an example, the parameterization function may give the most weight to the operating temperature such that the decision to change the corresponding climate/environmental conditions is largely weighted based on the operating temperature. Thus, other parameters such as the ability to transfer workloads, location in the data center 200, etc. are given less weight and do not impact the environmental conditions setpoint as much as the operating temperature. The weighting of the parameters in the parameterization function is not constant, and can be changed at any time to give more or less weight to a particular parameter to ensure that the workloads being performed in the data center 200 are operating appropriately and without performance loss. Such an example could include prioritizing expected/future workloads and determining the environmental conditions setpoint before the climate/environmental conditions require changing to proactively react to anticipated workload changes.

In some examples, the parameterization function may utilize a Kalman filter for weighing and estimating a parameter's importance. The Kalman Filter is an efficient optimal estimator (a set of mathematical equations) that provides a recursive computational methodology for estimating the state of a discrete-data controlled process from measurements that are typically noisy (e.g., temperature readings, electrical signals, etc.), while providing an estimate of the uncertainty of the estimates. Example parameters to the parameterization function are listed with respect to the sensor circuitry 1710, the workload circuitry 1730, and/or the local cooling circuitry 1740 above, and may include any singular or combination of computing/environmental parameters that may be determinative of the operation of the data center. Any other method of parameter estimation may be interchangeably used herein such as structured parameterization, model parameter estimation, neural networks/artificial intelligence, etc.

As disclosed above, in some examples, the environmental setpoint determination circuitry 1850 may determine that it is more energy efficient to cool the data center before workloads increase or even begin to maintain a temperature/humidity/etc. than to reactively cool based on temperatures exceeding allowable thresholds. Additionally, in some examples, the environmental setpoint determination circuitry 1850 may determine that it is more energy efficient to cease cooling the data center before workloads decrease and/or cease to allow temperature/humidity/etc. to drift within acceptable limits rather than to spending resources unnecessarily to cool when projections indicate the drifting temperatures will remain within allowable thresholds. Such an example reduces greenhouse gas emissions since it is more energy efficient to maintain a temperature than it is to reactively reach a temperature and it is more energy efficient to avoid active cooling when it is not needed to meet desired results.

Once the environmental setpoint determination circuitry 1850 determines the environmental conditions setpoint, the environmental setpoint determination circuitry 1850 determines whether the bi-directional guard bands allow for the environmental conditions setpoint to be achieved. (Block 2020). In some examples, the environmental conditions setpoint is unreachable based on the amount of HVAC cooling availability, inability to modify workloads, or any other singular or combination of factors. Moreover, in some examples, environmental conditions other than temperature and humidity such as noise, air quality, etc. are considered in determining the environmental conditions setpoint. In some examples, noise generated by the servers/computing devices/plots may impact the climate/environmental conditions setpoint. For instance, it may be necessary reduce fan speeds to protect operators (e.g., hearing protection) maintaining the data center at a cost of increased temperature. In such an example, the climate/environmental conditions setpoint may be changed to reduce the speed of the fans and allow a permissible increase in temperature. Any alternative or additional individual or combination of factors may be used and/or weighed to determine the climate/environmental conditions setpoint.

When the environmental setpoint determination circuitry 1850 determines that the bi-directional guard bands do not allow the environmental conditions setpoint to be achieved (e.g., block 2020 returns a result of NO), then the environmental setpoint determination circuitry 1850 updates the environmental conditions setpoint based on the bi-directional guard band limitations. (Block 2030). In some examples, the bi-directional guard bands include determining whether the HVAC system can handle the environmental conditions setpoint request, whether the current workloads being performed can still be performed at the environmental conditions setpoint, whether the environmental conditions setpoint violates any sort of risk policy in place to protect hardware and/or data, or any other form of indication that the environmental conditions setpoint cannot be reached and needs to be modified.

When the environmental setpoint determination circuitry 1850 determines that the bi-directional guard bands allow the environmental conditions setpoint to be achieved (e.g., block 2020 returns a result of YES) or when the environmental setpoint determination circuitry 1850 updated the environmental conditions setpoint based on limits applied based on the bi-directional guard bands, then the environmental setpoint determination circuitry 1850 defines the environmental conditions setpoint. (Block 2040). When the environmental conditions setpoint is defined, the climate/environmental conditions determination process 1940 ends.

FIG. 21 is a block diagram of an example processor platform 2100 structured to execute and/or instantiate the machine readable instructions and/or the operations of FIGS. 19 and/or 20 to implement the environmental controller circuitry 1750 of FIG. 18. The processor platform 2100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing device.

The processor platform 2100 of the illustrated example includes processor circuitry 2112. The processor circuitry 2112 of the illustrated example is hardware. For example, the processor circuitry 2112 can be implemented by one or more integrated circuits, logic circuits, FPGAs, microprocessors, CPUs, GPUs, DSPs, and/or microcontrollers from any desired family or manufacturer. The processor circuitry 2112 may be implemented by one or more semiconductor based (e.g., silicon based) devices. In this example, the processor circuitry 2112 implements the environmental setpoint determination circuitry 1850.

The processor circuitry 2112 of the illustrated example includes a local memory 2113 (e.g., a cache, registers, etc.). The processor circuitry 2112 of the illustrated example is in communication with a main memory including a volatile memory 2114 and a non-volatile memory 2116 by a bus 2118. The volatile memory 2114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2116 may be implemented by flash memory and/or any other desired type of memory device. Access to the main memory 2114, 2116 of the illustrated example is controlled by a memory controller 2117.

The processor platform 2100 of the illustrated example also includes interface circuitry 2120. The interface circuitry 2120 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2122 are connected to the interface circuitry 2120. The input device(s) 2122 permit(s) a user to enter data and/or commands into the processor circuitry 2112. The input device(s) 2122 can be implemented by, for example, a temperature and/or humidity sensor, a camera (still or video), a keyboard, a button, a mouse, a touchscreen, a track-pad, a trackball, and/or an isopoint device.

One or more output devices 2124 are also connected to the interface circuitry 2120 of the illustrated example. The output device(s) 2124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2120 of the illustrated example, thus, typically includes a graphics driver card, a graphics driver chip, and/or graphics processor circuitry such as a GPU.

The interface circuitry 2120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2126. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2100 of the illustrated example also includes one or more mass storage devices 2128 to store software and/or data. Examples of such mass storage devices 2128 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 2132, which may be implemented by the machine readable instructions of FIGS. 19 and/or 20, may be stored in the mass storage device 2128, in the volatile memory 2114, in the non-volatile memory 2116, and/or on a removable non-transitory computer readable storage medium such as a CD or DVD.

FIG. 22 is a block diagram of an example implementation of the processor circuitry 2112 of FIG. 21. In this example, the processor circuitry 2112 of FIG. 21 is implemented by a microprocessor 2200. For example, the microprocessor 2200 may be a general purpose microprocessor (e.g., general purpose microprocessor circuitry). The microprocessor 2200 executes some or all of the machine readable instructions of the flowcharts of FIGS. 19 and/or 20 to effectively instantiate the environmental controller circuitry 1750 of FIG. 18 as logic circuits to perform the operations corresponding to those machine readable instructions. In some such examples, the environmental controller circuitry 1750 of FIG. 18 is instantiated by the hardware circuits of the microprocessor 2200 in combination with the instructions. For example, the microprocessor 2200 may be implemented by multi-core hardware circuitry such as a CPU, a DSP, a GPU, an XPU, etc. Although it may include any number of example cores 2202 (e.g., 1 core), the microprocessor 2200 of this example is a multi-core semiconductor device including N cores. The cores 2202 of the microprocessor 2200 may operate independently or may cooperate to execute machine readable instructions. For example, machine code corresponding to a firmware program, an embedded software program, or a software program may be executed by one of the cores 2202 or may be executed by multiple ones of the cores 2202 at the same or different times. In some examples, the machine code corresponding to the firmware program, the embedded software program, or the software program is split into threads and executed in parallel by two or more of the cores 2202. The software program may correspond to a portion or all of the machine readable instructions and/or operations represented by the flowcharts of FIGS. 19 and/or 20.

The cores 2202 may communicate by a first example bus 2204. In some examples, the first bus 2204 may be implemented by a communication bus to effectuate communication associated with one(s) of the cores 2202. For example, the first bus 2204 may be implemented by at least one of an Inter-Integrated Circuit (I2C) bus, a Serial Peripheral Interface (SPI) bus, a PCI bus, or a PCIe bus. Additionally or alternatively, the first bus 2204 may be implemented by any other type of computing or electrical bus. The cores 2202 may obtain data, instructions, and/or signals from one or more external devices by example interface circuitry 2206. The cores 2202 may output data, instructions, and/or signals to the one or more external devices by the interface circuitry 2206. Although the cores 2202 of this example include example local memory 2220 (e.g., Level 1 (L1) cache that may be split into an L1 data cache and an L1 instruction cache), the microprocessor 2200 also includes example shared memory 2210 that may be shared by the cores (e.g., Level 2 (L2 cache)) for high-speed access to data and/or instructions. Data and/or instructions may be transferred (e.g., shared) by writing to and/or reading from the shared memory 2210. The local memory 2220 of each of the cores 2202 and the shared memory 2210 may be part of a hierarchy of storage devices including multiple levels of cache memory and the main memory (e.g., the main memory 2114, 2116 of FIG. 21). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2202 may be referred to as a CPU, DSP, GPU, etc., or any other type of hardware circuitry. Each core 2202 includes control unit circuitry 2214, arithmetic and logic (AL) circuitry (sometimes referred to as an ALU) 2216, a plurality of registers 2218, the local memory 2220, and a second example bus 2222. Other structures may be present. For example, each core 2202 may include vector unit circuitry, single instruction multiple data (SIMD) unit circuitry, load/store unit (LSU) circuitry, branch/jump unit circuitry, floating-point unit (FPU) circuitry, etc. The control unit circuitry 2214 includes semiconductor-based circuits structured to control (e.g., coordinate) data movement within the corresponding core 2202. The AL circuitry 2216 includes semiconductor-based circuits structured to perform one or more mathematic and/or logic operations on the data within the corresponding core 2202. The AL circuitry 2216 of some examples performs integer based operations. In other examples, the AL circuitry 2216 also performs floating point operations. In yet other examples, the AL circuitry 2216 may include first AL circuitry that performs integer based operations and second AL circuitry that performs floating point operations. In some examples, the AL circuitry 2216 may be referred to as an Arithmetic Logic Unit (ALU). The registers 2218 are semiconductor-based structures to store data and/or instructions such as results of one or more of the operations performed by the AL circuitry 2216 of the corresponding core 2202. For example, the registers 2218 may include vector register(s), SIMD register(s), general purpose register(s), flag register(s), segment register(s), machine specific register(s), instruction pointer register(s), control register(s), debug register(s), memory management register(s), machine check register(s), etc. The registers 2218 may be arranged in a bank as shown in FIG. 22. Alternatively, the registers 2218 may be organized in any other arrangement, format, or structure including distributed throughout the core 2202 to shorten access time. The second bus 2222 may be implemented by at least one of an I2C bus, a SPI bus, a PCI bus, or a PCIe bus

Each core 2202 and/or, more generally, the microprocessor 2200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2200 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 23 is a block diagram of another example implementation of the processor circuitry 2112 of FIG. 21. In this example, the processor circuitry 2112 is implemented by FPGA circuitry 2300. For example, the FPGA circuitry 2300 may be implemented by an FPGA. The FPGA circuitry 2300 can be used, for example, to perform operations that could otherwise be performed by the example microprocessor 2200 of FIG. 22 executing corresponding machine readable instructions. However, once configured, the FPGA circuitry 2300 instantiates the machine readable instructions in hardware and, thus, can often execute the operations faster than they could be performed by a general purpose microprocessor executing the corresponding software.

More specifically, in contrast to the microprocessor 2200 of FIG. 22 described above (which is a general purpose device that may be programmed to execute some or all of the machine readable instructions represented by the flowcharts of FIGS. 19 and/or 20 but whose interconnections and logic circuitry are fixed once fabricated), the FPGA circuitry 2300 of the example of FIG. 23 includes interconnections and logic circuitry that may be configured and/or interconnected in different ways after fabrication to instantiate, for example, some or all of the machine readable instructions represented by the flowcharts of FIGS. 19 and/or 20. In particular, the FPGA circuitry 2300 may be thought of as an array of logic gates, interconnections, and switches. The switches can be programmed to change how the logic gates are interconnected by the interconnections, effectively forming one or more dedicated logic circuits (unless and until the FPGA circuitry 2300 is reprogrammed). The configured logic circuits enable the logic gates to cooperate in different ways to perform different operations on data received by input circuitry. Those operations may correspond to some or all of the software represented by the flowcharts of FIGS. 19 and/or 20. As such, the FPGA circuitry 2300 may be structured to effectively instantiate some or all of the machine readable instructions of the flowcharts of FIGS. 19 and/or 20 as dedicated logic circuits to perform the operations corresponding to those software instructions in a dedicated manner analogous to an ASIC. Therefore, the FPGA circuitry 2300 may perform the operations corresponding to the some or all of the machine readable instructions of FIGS. 19 and/or 20 faster than the general purpose microprocessor can execute the same.

In the example of FIG. 23, the FPGA circuitry 2300 is structured to be programmed (and/or reprogrammed one or more times) by an end user by a hardware description language (HDL) such as Verilog. The FPGA circuitry 2300 of FIG. 23, includes example input/output (I/O) circuitry 2302 to obtain and/or output data to/from example configuration circuitry 2304 and/or external hardware 2306. For example, the configuration circuitry 2304 may be implemented by interface circuitry that may obtain machine readable instructions to configure the FPGA circuitry 2300, or portion(s) thereof. In some such examples, the configuration circuitry 2304 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2306 may be implemented by external hardware circuitry. For example, the external hardware 2306 may be implemented by the microprocessor 2200 of FIG. 22. The FPGA circuitry 2300 also includes an array of example logic gate circuitry 2308, a plurality of example configurable interconnections 2310, and example storage circuitry 2312. The logic gate circuitry 2308 and the configurable interconnections 2310 are configurable to instantiate one or more operations that may correspond to at least some of the machine readable instructions of FIGS. 19 and/or 20 and/or other desired operations. The logic gate circuitry 2308 shown in FIG. 23 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2308 to enable configuration of the electrical structures and/or the logic gates to form circuits to perform desired operations. The logic gate circuitry 2308 may include other electrical structures such as look-up tables (LUTs), registers (e.g., flip-flops or latches), multiplexers, etc.

The configurable interconnections 2310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2308 to program desired logic circuits.

The storage circuitry 2312 of the illustrated example is structured to store result(s) of the one or more of the operations performed by corresponding logic gates. The storage circuitry 2312 may be implemented by registers or the like. In the illustrated example, the storage circuitry 2312 is distributed amongst the logic gate circuitry 2308 to facilitate access and increase execution speed.

The example FPGA circuitry 2300 of FIG. 23 also includes example Dedicated Operations Circuitry 2314. In this example, the Dedicated Operations Circuitry 2314 includes special purpose circuitry 2316 that may be invoked to implement commonly used functions to avoid the need to program those functions in the field. Examples of such special purpose circuitry 2316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2300 may also include example general purpose programmable circuitry 2318 such as an example CPU 2320 and/or an example DSP 2322. Other general purpose programmable circuitry 2318 may additionally or alternatively be present such as a GPU, an XPU, etc., that can be programmed to perform other operations.

Although FIGS. 22 and 23 illustrate two example implementations of the processor circuitry 2112 of FIG. 21, many other approaches are contemplated. For example, as mentioned above, modern FPGA circuitry may include an on-board CPU, such as one or more of the example CPU 2320 of FIG. 23. Therefore, the processor circuitry 2112 of FIG. 21 may additionally be implemented by combining the example microprocessor 2200 of FIG. 22 and the example FPGA circuitry 2300 of FIG. 23. In some such hybrid examples, a first portion of the machine readable instructions represented by the flowcharts of FIGS. 19 and/or 20 may be executed by one or more of the cores 2202 of FIG. 22, a second portion of the machine readable instructions represented by the flowcharts of FIGS. 19 and/or 20 may be executed by the FPGA circuitry 2300 of FIG. 23, and/or a third portion of the machine readable instructions represented by the flowcharts of FIGS. 19 and/or 20 may be executed by an ASIC. It should be understood that some or all of the circuitry of FIG. 18 may, thus, be instantiated at the same or different times. Some or all of the circuitry may be instantiated, for example, in one or more threads executing concurrently and/or in series. Moreover, in some examples, some or all of the circuitry of FIG. 18 may be implemented within one or more virtual machines and/or containers executing on the microprocessor.

In some examples, the processor circuitry 2112 of FIG. 21 may be in one or more packages. For example, the microprocessor 2200 of FIG. 22 and/or the FPGA circuitry 2300 of FIG. 23 may be in one or more packages. In some examples, an XPU may be implemented by the processor circuitry 2112 of FIG. 21, which may be in one or more packages. For example, the XPU may include a CPU in one package, a DSP in another package, a GPU in yet another package, and an FPGA in still yet another package.

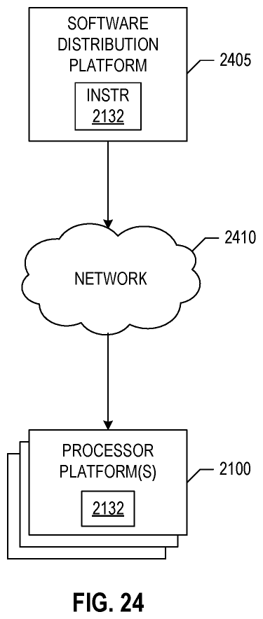

A block diagram illustrating an example software distribution platform 2405 to distribute software such as the example machine readable instructions 2132 of FIG. 21 to hardware devices owned and/or operated by third parties is illustrated in FIG. 24. The example software distribution platform 2405 may be implemented by any computer server, data facility, cloud service, etc., capable of storing and transmitting software to other computing devices. The third parties may be customers of the entity owning and/or operating the software distribution platform 2405. For example, the entity that owns and/or operates the software distribution platform 2405 may be a developer, a seller, and/or a licensor of software such as the example machine readable instructions 2132 of FIG. 21. The third parties may be consumers, users, retailers, OEMs, etc., who purchase and/or license the software for use and/or re-sale and/or sub-licensing. In the illustrated example, the software distribution platform 2405 includes one or more servers and one or more storage devices. The storage devices store the machine readable instructions 2132, which may correspond to the example machine readable instructions of FIGS. 19 and/or 20, as described above. The one or more servers of the example software distribution platform 2405 are in communication with an example network 2410, which may correspond to any one or more of the Internet and/or any of the example networks 2126 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2132 from the software distribution platform 2405. For example, the software, which may correspond to the example machine readable instructions of FIGS. 19 and/or 20, may be downloaded to the example processor platform 2100, which is to execute the machine readable instructions 2132 to implement the environmental controller circuitry 1750. In some examples, one or more servers of the software distribution platform 2405 periodically offer, transmit, and/or force updates to the software (e.g., the example machine readable instructions 2132 of FIG. 21) to ensure improvements, patches, updates, etc., are distributed and applied to the software at the end user devices.

From the foregoing, it will be appreciated that example systems, methods, apparatus, and articles of manufacture have been disclosed that auto tune data center cooling based on workloads. Disclosed systems, methods, apparatus, and articles of manufacture improve the efficiency of a data center including plots of servers/computing devices by monitoring and changing/recommending changes to climate/environmental conditions in the data center due to current device workload status, expected/future workload status, cooling status, and/or current climate/environmental conditions. Disclosed systems, methods, apparatus, and articles of manufacture are accordingly directed to one or more improvement(s) in the operation of machines such as a computer or other electronic and/or mechanical devices. Examples disclosed herein reduce the emissions of greenhouse gases and allow data centers to more effectively control climate/environmental conditions.

Example methods, apparatus, systems, and articles of manufacture to auto tune data center cooling based on workloads are disclosed herein. Further examples and combinations thereof include the following:

Example 1 includes an apparatus comprising memory, machine readable instructions, and processor circuitry to at least one of instantiate or execute the machine readable instructions to determine an environmental conditions setpoint based on information related to operation of devices within a data center, the information including at least one of a future workload status or a current workload status of the devices, and output the environmental conditions setpoint to facilitate control of a climate/environmental condition in the data center.

Example 2 includes the apparatus of example 1, wherein the environmental conditions setpoint includes a temperature setpoint.

Example 3 includes the apparatus of example 1, wherein the environmental conditions setpoint includes a humidity setpoint.

Example 4 includes the apparatus of example 1, wherein the information includes computing performance parameters of the devices.

Example 5 includes the apparatus of example 1, wherein the information includes a cooling status of the devices within the data center.

Example 6 includes the apparatus of example 5, wherein the cooling status includes at least one of a device temperature, a temperature limit, a location of the device within the data center, or cooling headroom availability.

Example 7 includes the apparatus of example 1, wherein the processor circuitry is to obtain a current environment temperature of a plot of the data center.

Example 8 includes the apparatus of example 1, wherein the processor circuitry is to obtain a current humidity value of a plot of the data center.

Example 9 includes the apparatus of example 1, wherein the environmental conditions setpoint includes a plurality of setpoints and the data center includes a plurality of plots, respective ones of the plots including a subset of the devices within the data center, the processor circuitry to output different ones of the environmental conditions setpoints for different ones of the plots.

Example 10 includes the apparatus of example 1, wherein the processor circuitry is to output the environmental conditions setpoint to automatically cause a change to the environmental conditions.

Example 11 includes the apparatus of example 1, wherein the processor circuitry is to output the environmental conditions setpoint to a display.

Example 12 includes the apparatus of example 1, wherein the processor circuitry is to limit the environmental conditions setpoint based on a bi-directional guard band to at least one of protect the devices in the data center or maintain a performance level for the devices.

Example 13 includes the apparatus of example 1, wherein the processor circuitry is to execute a parameterization function based on the information to determine the environmental conditions setpoint, and update the environmental conditions setpoint using a bi-directional guard band.

Example 14 includes a non-transitory machine readable storage medium comprising instructions to cause processor circuitry to at least determine an environmental conditions setpoint based on information related to operation of devices within a data center, the information including at least one of a future workload status or a current workload status of the devices, and output the environmental conditions setpoint.

Example 15 includes the non-transitory machine readable storage medium of example 14, wherein the environmental conditions setpoint includes a temperature setpoint.

Example 16 includes the non-transitory machine readable storage medium of example 14, wherein the environmental conditions setpoint includes a humidity setpoint.

Example 17 includes the non-transitory machine readable storage medium of example 14, wherein the information includes computing performance parameters of the devices.

Example 18 includes the non-transitory machine readable storage medium of example 14, wherein the information includes at least one of a device temperature, a temperature limit, a location of device within the data center, or cooling headroom availability.

Example 19 includes the non-transitory machine readable storage medium of example 14, wherein the instructions cause the processor circuitry to limit the environmental conditions setpoint based on a bi-directional guard band to at least one of protect the devices in the data center or maintain a performance level for the devices.

Example 20 includes the non-transitory machine readable storage medium of example 14, wherein the instructions cause the processor circuitry to execute a parameterization function based on the information to determine the environmental conditions setpoint, and update the environmental conditions setpoint using a bi-directional guard band.

Example 21 includes a method to control environmental conditions in a data center, the method comprising determining a plurality of environmental conditions setpoints based on information related to operation of devices within the data center, the data center including a plurality of plots, respective ones of the plots including a corresponding subset of the devices, the information including at least one of a future workload status or a current workload status of the devices, and outputting the environmental conditions setpoints to respectively control corresponding environmental conditions for different ones of the plurality of plots in the data center where the devices are located.

Example 22 includes the method of example 21, further including establishing a temperature setpoint.

Example 23 includes the method of example 21, further including establishing a humidity setpoint.

Example 24 includes the method of example 21, wherein the information includes computing performance parameters of the devices.

Example 25 includes the method of example 21, further including obtaining a cooling status of the devices within the data center.

Example 26 includes the method of example 25, wherein obtaining the cooling status includes obtaining at least one of a device temperature, a temperature limit, a location of device within the data center, or cooling headroom availability.

Example 27 includes the method of example 21, further including outputting the environmental conditions setpoints to automatically cause a change to the corresponding environmental conditions of the corresponding plot.

Example 28 includes the method of example 21, further including outputting the environmental conditions setpoints to a display.

Example 29 includes the method of example 21, further including limiting the environmental conditions setpoints based on corresponding bi-directional guard bands to at least one of protect the devices in the corresponding plots or maintain a performance level for the devices in the corresponding plots.

Example 30 includes the method of example 21, further including executing a parameterization function based on the information to determine the environmental conditions setpoints, and updating the environmental conditions setpoints using a bi-directional guard band.

Example 31 includes the method of example 21, further including reducing greenhouse gas emissions by predictively cooling the data center prior to the future workload being performed.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
memory;
machine readable instructions; and
processor circuitry to at least one of instantiate or execute the machine readable instructions to:
determine an environmental conditions setpoint based on information related to operation of devices within a data center, the information including at least one of a future workload status or a current workload status of the devices; and
output the environmental conditions setpoint to facilitate control of an environmental condition in the data center.

2. The apparatus of claim 1, wherein the environmental conditions setpoint includes a temperature setpoint.

3. The apparatus of claim 1, wherein the environmental conditions setpoint includes a humidity setpoint.

4. The apparatus of claim 1, wherein the information includes computing performance parameters of the devices.

5. The apparatus of claim 1, wherein the information includes a cooling status of the devices within the data center.

6. The apparatus of claim 5, wherein the cooling status includes at least one of a device temperature, a temperature limit, a location of the device within the data center, or cooling headroom availability.

7. The apparatus of claim 1, wherein the processor circuitry is to obtain a current environment temperature of a plot of the data center.

8. The apparatus of claim 1, wherein the processor circuitry is to obtain a current humidity value of a plot of the data center.

9. The apparatus of claim 1, wherein the environmental conditions setpoint includes a plurality of setpoints and the data center includes a plurality of plots, respective ones of the plots including a subset of the devices within the data center, the processor circuitry to output different ones of the environmental conditions setpoints for different ones of the plots.

10. The apparatus of claim 1, wherein the processor circuitry is to output the environmental conditions setpoint to automatically cause a change to the environmental conditions.

11. The apparatus of claim 1, wherein the processor circuitry is to output the environmental conditions setpoint to a display.

12. The apparatus of claim 1, wherein the processor circuitry is to limit the environmental conditions setpoint based on a bi-directional guard band to at least one of protect the devices in the data center or maintain a performance level for the devices.

13. The apparatus of claim 1, wherein the processor circuitry is to:
execute a parameterization function based on the information to determine the environmental conditions setpoint; and
update the environmental conditions setpoint using a bi-directional guard band.

14. A non-transitory machine readable storage medium comprising instructions to cause processor circuitry to at least:
determine an environmental conditions setpoint based on information related to operation of devices within a data center, the information including at least one of a future workload status or a current workload status of the devices; and
output the environmental conditions setpoint.

15. The non-transitory machine readable storage medium of claim 14, wherein the environmental conditions setpoint includes a temperature setpoint.

16. The non-transitory machine readable storage medium of claim 14, wherein the environmental conditions setpoint includes a humidity setpoint.

17. The non-transitory machine readable storage medium of claim 14, wherein the information includes computing performance parameters of the devices.

18. The non-transitory machine readable storage medium of claim 14, wherein the information includes at least one of a device temperature, a temperature limit, a location of device within the data center, or cooling headroom availability.

19. The non-transitory machine readable storage medium of claim 14, wherein the instructions cause the processor circuitry to limit the environmental conditions setpoint based on a bi-directional guard band to at least one of protect the devices in the data center or maintain a performance level for the devices.

20. The non-transitory machine readable storage medium of claim 14, wherein the instructions cause the processor circuitry to:
execute a parameterization function based on the information to determine the environmental conditions setpoint; and
update the environmental conditions setpoint using a bi-directional guard band.

21. A method to control environmental conditions in a data center, the method comprising:
determining a plurality of environmental conditions setpoints based on information related to operation of devices within the data center, the data center including a plurality of plots, respective ones of the plots including a corresponding subset of the devices, the information including at least one of a future workload status or a current workload status of the devices; and
outputting the environmental conditions setpoints to respectively control corresponding environmental conditions for different ones of the plurality of plots in the data center where the devices are located.

22-26. (canceled)

27. The method of claim 21, further including outputting the environmental conditions setpoints to automatically cause a change to the corresponding environmental conditions of the corresponding plot.

28. (canceled)

29. The method of claim 21, further including limiting the environmental conditions setpoints based on corresponding bi-directional guard bands to at least one of protect the devices in the corresponding plots or maintain a performance level for the devices in the corresponding plots.

30. The method of claim 21, further including:
executing a parameterization function based on the information to determine the environmental conditions setpoints; and
updating the environmental conditions setpoints using a bi-directional guard band.

31. The method of claim 21, further including reducing greenhouse gas emissions by predictively cooling the data center prior to the future workload being performed.
